SEQUENCE LISTING (3 sequences)

SEQ ID NO: 1 - DNA, 27 bp, Bacillus anthracis
ggattattgttaaatattgataaggat

SEQ ID NO: 2 - DNA, 27 bp, Bacillus anthracis
ttcggcggtggcccgcggtcgccttcg

SEQ ID NO: 3 - DNA, 27 bp, Artificial Sequence
  Description of Artificial Sequence Synthetic oligonucleotide
atccttatcaatatttaacaataatcc

(19) United States
(12) Patent Application Publication
(10) Pub. No.: US 2010/0317124 A1
(43) Pub. Date: Dec. 16, 2010

(54) METAL-CONTAINING NANOMEMBRANES FOR MOLECULAR SENSING

(76) Inventors: Yong Hyup Kim, Seoul (KR); Tae June Kang, Seoul (KR)

Correspondence Address: Seoul National University Research;Development Business Foundation, San 56-1 Sillim-dong, Gwanak-gu, Seoul, 151-742, KR

(21) Appl. No.: 12/197,716

(22) Filed: Aug. 25, 2008

(51) Int. Cl. G01N 27/00; B05D 5/12; H05K 13/00

(52) U.S. Cl. 436/149; 422/68.1; 422/82.01; 427/123; 29/592.1; 977/742

(57) ABSTRACT

A sensor includes a first support having at least one opening; a metal-containing nanomembrane associated with the at least one opening and configured to interact with at least one molecular species; and at least one electrode configured to sense one or more interactions of the at least one molecular species with the metal-containing nanomembrane.

### BACKGROUND

Recently, a great deal of research has been carried out in order to develop label-free and reusable biosensors with high sensitivity that can also be used to detect configurational variations of biomolecules. For example, microcantilever beams have been utilized to detect biological molecules by measuring the change in differential surface stress induced by the adsorption of biological molecules on the surface of the beams.

Microcantilever-based biosensors, however, have a number of limitations. Although the size of microcantilever-based biosensors may be as small as hundreds of micrometers, bulky and expensive position sensitive detectors and optical detection units, such as laser reflection interferometers, need to be coupled with such sensors in order to detect the nanoscale deflection generated by the adsorption of biomolecules, making it difficult and costly to miniaturize such sensors. Additionally, because it is very difficult to fabricate flat microcantilevers using only metal due to the residual stress gradient of the metal, typically silicon or silicon nitride is utilized as a rigid and flat beam structure under the metal layer. Additional surface modification of the metal-coated silicon cantilevers is typically required to immobilize the probe molecules and enhance biocompatibility. Such asymmetric cantilever structures having different thermal expansion coefficients along the thickness direction of the cantilever may cause a thermomechanical deflection even under small temperature variations, which is a critical noise factor for microcantilever-based biosensors. Further, while biomolecular interactions should ideally take place on only one side of the cantilever, since most biomolecular experiments are carried out in a liquid phase the molecules moving in the liquid can also bind nonspecifically to the other side of the cantilever, producing undesired background signals.

### SUMMARY

Various embodiments of sensors are disclosed herein. In accordance with one aspect by way of non-limiting example, a sensor may include a first support having at least one opening, a metal-containing nanomembrane associated with the at least one opening and configured to interact with at least one molecular species, and at least one electrode configured to sense one or more interactions of the at least one molecular species with the metal-containing nanomembrane.

In another aspect, the present disclosure provides a method for making a sensor, which may involve associating a metal-containing nanomembrane with an opening of a first support, where the metal-containing nanomembrane is configured to interact with at least one molecular species, and positioning at least one electrode on one side of the metal-containing nanomembrane under conditions effective to allow the at least one electrode to sense one or more interactions of the at least one molecular species with the metal-containing nanomembrane.

In another aspect, the present disclosure provides a method for detecting at least one molecular species by using the above sensor.

In another aspect, the present disclosure provides a device for detecting at least one molecular species including the above sensor.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a schematic diagram of an illustrative embodiment of a sensor.

FIG. 2 is a schematic diagram of an illustrative embodiment of a sensor interacting with at least one molecular species.

FIGS. 3A-D are schematic diagrams of an illustrative embodiment of a method for fabricating a lower part of a sensor comprising a metal-containing nanomembrane.

FIGS. 4A-C are schematic diagrams of an illustrative embodiment of a method for fabricating a lower part of a sensor comprising a metal/carbon nanotube-containing nanomembrane.

FIGS. 5A-B are schematic diagrams of an illustrative embodiment of a method for fabricating an upper part of a sensor.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented here. It will be readily understood that the components of the present disclosure may be arranged and designed in a wide variety of different configurations. Those of ordinary skill will appreciate that the functions performed in the methods may be implemented in differing order, and that the outlined steps are provided only as examples, and some of the steps may be optional, combined into fewer steps, or expanded to include additional steps while still being encompassed within the scope of the claims.

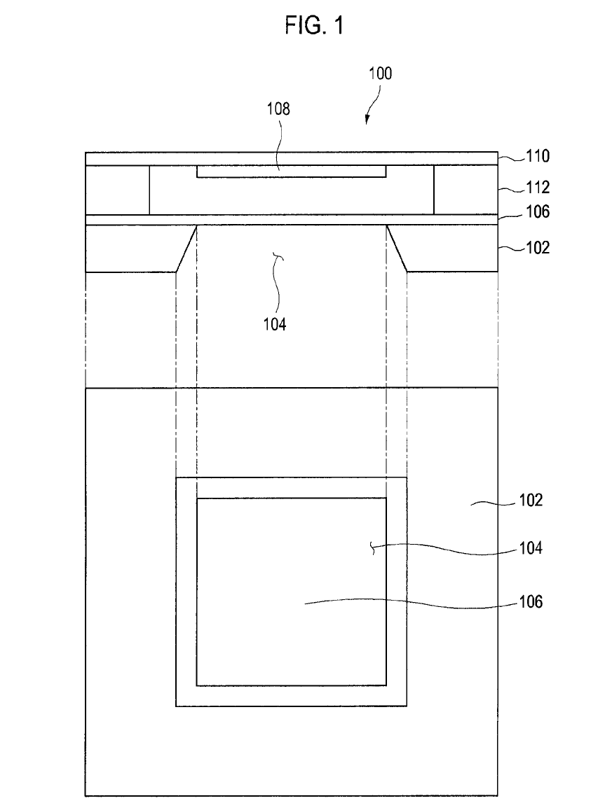

In one aspect, the present disclosure provides for a sensor comprising a metal-containing nanomembrane and an electrode. Referring to FIG. 1, a front view and a bottom view of an illustrative embodiment of a sensor 100 is shown. In certain embodiments, the sensor 100 may include a first support 102 having at least one opening 104, a metal-containing nanomembrane 106 associated with the at least one opening 104, and at least one electrode 108. The metal-containing nanomembrane 106 is configured to interact with at least one molecular species, while the at least one electrode 108 is configured to sense one or more interactions of the at least one molecular species with the metal-containing nanomembrane 106. In some embodiments, a layer of insulating material may optionally be positioned between the first support 102 and the metal-containing nanomembrane 106.

In some embodiments, at least a portion of the metal-containing nanomembrane 106 may be suspended over the opening 104 and configured to interact with or bind the at least one molecular species. The portion of the metal-containing nanomembrane 106 that is suspended over the opening 104 of the first support 102, as well as the opening 104, may have sizes ranging from about 50 μm to about 1000 μm in width/length. In some embodiments, the portion of the metal-containing nanomembrane 106 that is suspended over the opening 104 may range from about 100 μm to about 1000 μm, from about 200 μm to about 1000 μm, from about 400 μm to about 1000 μm, from about 600 μm to about 1000 μm, from about 800 μm to about 1000 μm, from about 50 μm to about 100 μm, from about 50 μm to about 200 μm, from about 50 μm to about 400 μm, from about 50 μm to about 600 μm, from about 50 μm to about 800 μm, from about 100 μm to about 200 μm, from about 200 μm to about 400 μm, from about 400 μm to about 600 μm, or from about 600 μm to about 800 μm in width/length. In other embodiments, the portion of the metal-containing nanomembrane 106 that is suspended over the opening 104 may be about 50 μm, about 100 μm, about 200 μm, about 400 μm, about 600 μm, about 800 μm, or about 1000 μm in width/length.

In some embodiments, the metal-containing nanomembrane may include any metal capable of interacting with molecular species, such as but not limited to, Ti, Cr, Ni, Cu, Zn, Ag, Pt, and Au. In other embodiments, the metal-containing nanomembrane may further include carbon nanotubes (CNTs). The CNTs may include, but are not limited to, single-walled carbon nanotubes (SWNTs) and multi-walled carbon nanotubes (MWNTs) having a purity of about 80%, about 85%, about 90%, about 95%, and about 99%. When CNTs are incorporated into the nanomembrane, the CNTs may enhance the mechanical properties of the nanomembrane by preventing the propagation of or bridging the cracks of the nanomembrane.

The thickness of the nanomembrane in the sensor provided by the present disclosure may affect the performance of the sensor. If the nanomembrane is too thin, the nanomembrane may be easily damaged. On the other hand, if the nanomembrane is too thick, the nanomembrane may be too rigid and lack the necessary flexibility and sensitivity. The thickness of the metal-containing nanomembrane may vary depending on the metal or the presence or absence of CNTs in the nanomembrane. For example, when metals with higher strength, such as Cr or Ni, and/or CNTs are contained in the metal-containing nanomembrane, it may be easier to make a metal-containing nanomembrane that is thin and flexible. On the other hand, when more fragile metals are used and/or there are no CNTs in the metal-containing nanomembrane, it may be necessary to make a thicker metal-containing nanomembrane. In certain embodiments, the metal-containing nanomembrane may have a thickness ranging from about 1 nm to about 50 nm. In some embodiments, the thickness of the metal-containing nanomembrane may range from about 5 nm to about 50 nm, from about 10 nm to about 50 nm, from about 20 nm to about 50 nm, from about 30 nm to about 50 nm, from about 40 nm to about 50 nm, from about 1 nm to about 5 nm, from about 1 nm to about 10 nm, from about 1 nm to about 20 nm, from about 1 nm to about 30 nm, from about 1 nm to about 40 nm, from about 5 nm to about 10 nm, from about 10 nm to about 20 nm, from about 20 nm to about 30 nm, or from about 30 nm to about 40 nm. In other embodiments, the thickness of the metal-containing nanomembrane may be about 1 nm, about 5 nm, about 10 nm, about 20 nm, about 30 nm, about 40 nm, or about 50 nm. The thickness of the metal-containing nanomembrane may be measured by atomic force microscopy techniques and the like.

As illustrated in FIG. 1, in certain embodiments, the at least one electrode 108 may be associated with a second support 110 and may be positioned at a predetermined distance from the metal-containing nanomembrane 106. In some embodiments, at least one set of spacers 112 are present between the metal-containing nanomembrane 106 and the electrode 108 or the second support 110 to maintain the predetermined distance. The predetermined distance between the metal-containing nanomembrane 106 and the electrode 108 is selected such that a change of capacitance between the metal-containing nanomembrane 106 and the electrode 108 resulting from a deflection of the metal-containing nanomembrane 106 could be measured by a detection unit. For example, if the predetermined distance between the metal-containing nanomembrane 106 and the electrode 108 is too large and the metal-containing nanomembrane 106 deflects only to a small extent, the capacitance change may be too small to be detectable. The predetermined distance between the metal-containing nanomembrane 106 and the electrode 108 may vary depending on the type of metal, since the metal-containing nanomembrane 106 may deflect to a greater or lesser extent depending on the type of metal. The predetermined distance may range from about 1 μm to about 10 μm. In some embodiments, the predetermined distance may range from about 2.5 μm to about 10 μm, from about 5 μm to about 10 μm, from about 7.5 μm to about 10 μm, from about 1 μm to about 2.5 μm, from about 1 μm to about 5 μm, from about 1 μm to about 7.5 μm, from about 2.5 μm to about 5 μm, or from about 5 μm to about 7.5 μm. In other embodiments, the predetermined distance may be about 1 μm, about 2.5 μm, about 5 μm, about 7.5 μm, or about 10 μm.

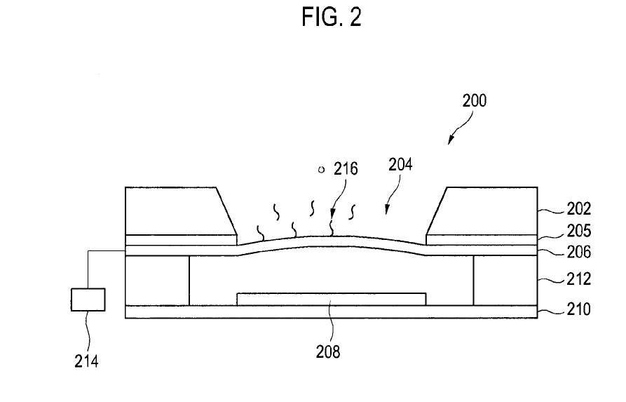

In certain embodiments, the sensor may further include at least one detection unit 214 coupled to the metal-containing nanomembrane 206 or the electrode 208, as illustrated in FIG. 2. Referring to FIG. 2, an illustrative embodiment of a sensor 200 measuring an interaction with at least one molecular species 216 is shown. The sensor shown in FIG. 2 is an upside down form of the same sensor shown in FIG. 1, where the sensor may include a first support 202 having at least one opening 204, a metal-containing nanomembrane 206 associated with the at least one opening 204, and at least one electrode 208. In some embodiments, a layer of insulating material 205 may be positioned between the first support 202 and the metal-containing nanomembrane 206. Further, the electrode 208 may be associated with the second support 210 and positioned at a predetermined distance from the metal-containing nanomembrane 206 by a set of spacers 212. As illustrated in FIGS. 1 and 2, the metal-containing nanomembrane 206 blocks the flow of any vapor/liquid sample containing the molecular species 216 to be detected from passing to the other side of the metal-containing nanomembrane 206. As illustrated in FIG. 2, the molecular species 216 to be detected interacts with the metal-containing nanomembrane 206 inside the opening 204, where the at least one electrode 208 senses one or more interactions of the molecular species 216 with the metal-containing nanomembrane 206.

If the metal-containing nanomembrane 206 is configured to bind or to interact with the molecular species 216, the molecular species 216 may bind to or associate with the metal-containing nanomembrane 206 and cause the metal-containing nanomembrane 206 to deflect, resulting in a change in the distance between the metal-containing nanomembrane 206 and the electrode 208, as illustrated in FIG. 2. This change in distance, in turn, results in a change of capacitance between the metal-containing nanomembrane 206 and the electrode 208. It may take from about a few seconds to about a few tens of minutes for the capacitance measurement value to stabilize and become constant, due to the time it takes for the molecular species 216 to be detected to bind or associate with the metal-containing nanomembrane 206. While FIG. 2 illustrates a sensor 200 having a metal-containing nanomembrane 206 deflected in an upward direction, it is also possible for the metal-containing nanomembrane 206 to be deflected in a downward direction. In certain embodiments, the detection unit 214 may be configured to detect the deflection of the metal-containing nanomembrane 206 caused by the interactions of the molecular species 216 with the metal-containing nanomembrane 206.

In some embodiments, the detection unit 214 may be configured to detect the molecular species 216 at least partially based on a capacitive response. The detection unit 214 may be a capacitance meter capable of monitoring the change in capacitance, e.g., AD7746 Evaluation board (Analog Devices, Inc., Norwood, Mass.). In other embodiments, the detection unit 214 may be configured to identify the capacitive response as a response that indicates the presence and/or concentration of the molecular species 216. For example, the detection unit 214 may have a display monitor indicating the presence or absence and/or concentration of the detected molecules.

The sensor in accordance with the present disclosure detects molecules based on the interactions between the flexible metal-containing nanomembrane and the molecular species. In certain embodiments, the sensor may utilize the various interactions between metal-containing surfaces and biological or chemical substances, such as the spontaneous assembly of thiol functional groups from solution or vapor onto gold-containing surfaces. For example, synthetic thiol-modified oligonucleotides can covalently bind to the gold-containing nanomembrane. In operation, the binding of oligonucleotides on a gold-containing nanomembrane induces the deflection of the nanomembrane in the sensor, resulting in a change of the distance between the nanomembrane and the electrode. The change of the distance between the nanomembrane and the electrode in the sensor causes a change in capacitance between the nanomembrane and the electrode, the capacitance being inversely proportional to the distance. Such a capacitive response is identified as a response indicating the presence and/or concentration of the oligonucleotides in the sensor.

While a buffer solution containing none of the molecules to be detected causes no capacitance change, a negative capacitance change detected by a detection unit would indicate an upward deflection of the nanomembrane caused by the binding of molecules onto the top surface of the nanomembrane. Without wishing to be bound by a particular theory of action, the nanomechanics of the above-described deflection behavior may be explained as follows. When a molecule with high flexibility is in a free solution with a low ionic strength, the molecule usually adopts a configuration that maximizes its entropy, resulting in an entangled shape. When the molecule is grafted onto a surface such as a nanomembrane, however, intermolecular interactions influence its configuration. Thus, if the grafting density of the molecule on the surface of a nanomembrane is increased, each molecule will be forced to occupy a region of space that is smaller than its natural size in a free solution, because of the intersegment interactions resulting from steric or electrostatic repulsion, for example. This molecular deformation reduces the configurational entropy, which can be alleviated by adsorption onto a convex surface, since the curvature allows each molecule to occupy a larger region of space as the distance from the surface increases. This phenomenon produces an entropic driving force for forming a curved interface, in addition to the intersegment energy. These forces are balanced with the strain energy of bending the nanomembrane, resulting in an equilibrium value for curvature and deflection of the nanomembrane.

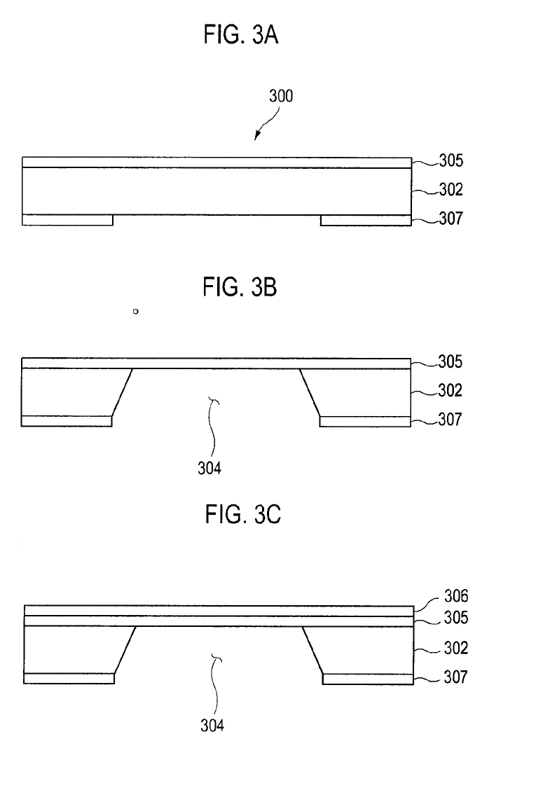

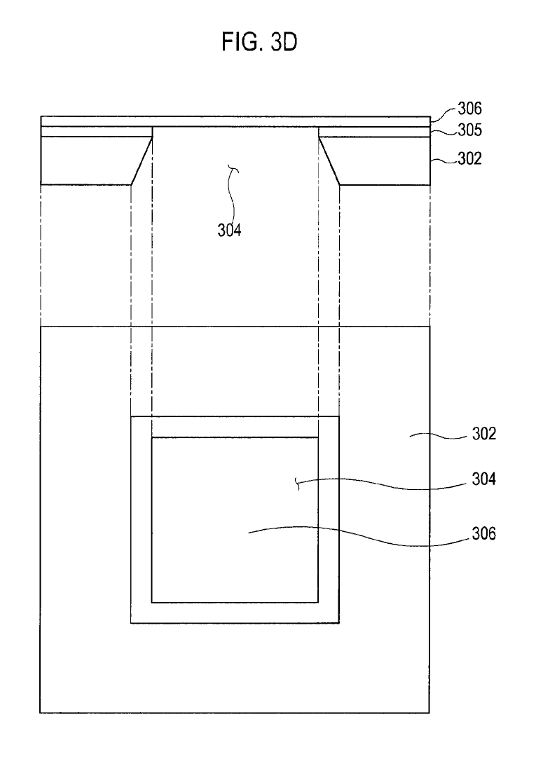

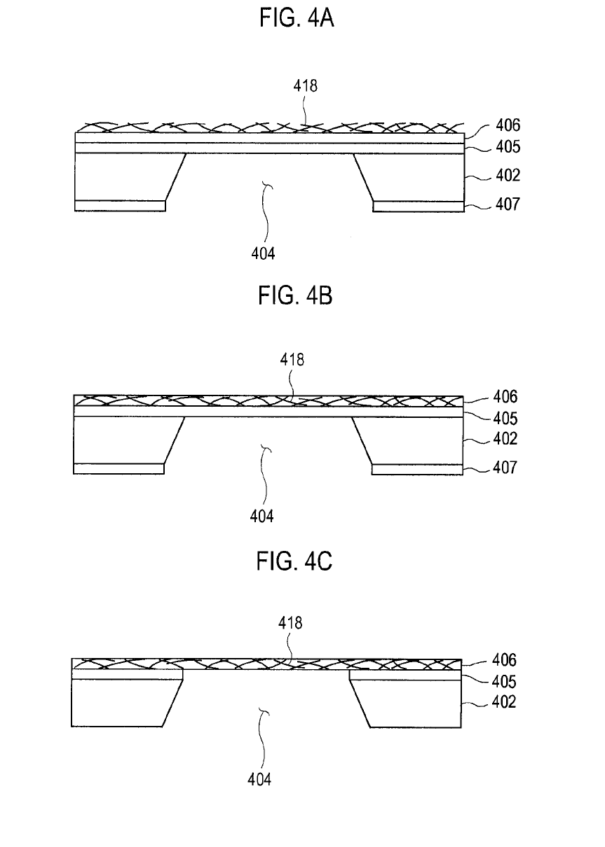

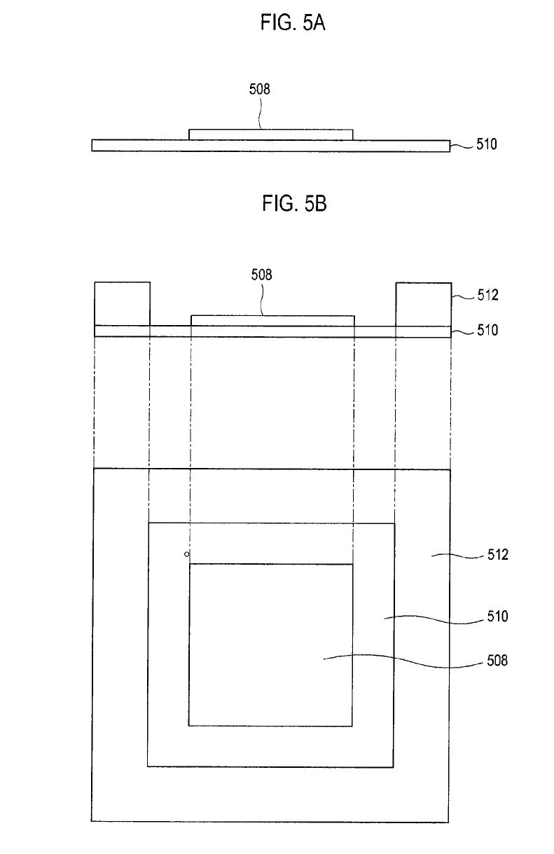

In another aspect, the present disclosure also provides for methods for making a sensor. Referring to FIGS. 3A-D, FIGS. 4 A-C, and FIGS. 5A-B, illustrative embodiments of methods for fabricating the lower part and upper part of a sensor comprising a metal-containing nanomembrane are shown. Initially, as illustrated in FIGS. 3A-D, the lower part of the sensor may be fabricated by associating a metal-containing nanomembrane 306 with an opening 304 of a first support 300, using a bottom-up approach. The metal-containing nanomembrane 306 is associated with the at least one opening 304 and configured to interact with at least one molecular species.

First, as illustrated in FIG. 3A, a first layer of insulating material 305 is deposited on one side of a base layer 302, while a second layer of insulating material 307 is deposited on the other side of the base layer 302, leaving a portion of the base layer 302 uncovered to form the first support 300. Suitable materials for the base layer 302 include, but are not limited to, glass, glass wafer, silicon wafer, quartz, and plastic. The length and/or width of the base layer 302 may range, without limitation, from about 100 μm to about 5000 μm. In some embodiments, the length and/or width of the base layer 302 may range from about 500 μm to about 5000 μM, from about 1000 μm to about 5000 μm, from about 2000 μm to about 5000 μm, from about 3000 μm to about 5000 μm, from about 4000 μm to about 5000 μm, from about 100 μm to about 500 μm, from about 100 μm to about 1000 μm, from about 100 μm to about 2000 μm, from about 100 μm to about 3000 μm, from about 100 μm to about 4000 μm, from about 100 μm to about 500 μm, from about 500 μm to about 1000 μm, from about 1000 μm to about 2000 μm, from about 2000 μm to about 3000 μm, or from about 3000 μm to about 4000 μm. In other embodiments, the length and/or width of the base layer 302 may be about 100 μm, about 500 μm, about 1000 μm, about 2000 μm, about 3000 μm, about 4000 μm, or about 5000 μm. The thickness of the base layer 302 may range, without limitation, from about 50 μm to about 500 μm. In some embodiments, the thickness of the base layer 302 may range from about 100 μm to about 500 μm, from about 200 μm to about 500 μm, from about 300 μm to about 500 μm, from about 400 μm to about 500 μm, from about 50 μm to about 100 μm, from about 50 μm to about 200 μm, from about 50 μm to about 300 μm, from about 50 μm to about 400 μm, from about 100 μm to about 200 μm, from about 200 μm to about 300 μm, or from about 300 μm to about 400 μm. In other embodiments, the thickness of the base layer 302 may be about 50 μm, about 100 μm, about 200 μm, about 300 μm, about 400 μm, or about 500 μm.

The first layer of insulating material 305 and the second layer of insulating material 307 may include, but are not limited to, silicon nitride and silicon dioxide. The length and/or width of the first layer of insulating material 305 and the second layer of insulating material 307 may be similar to those for the base layer 302 described above. The thickness of the first layer of insulating material 305 and the second layer of insulating material 307 may range, without limitation, from about 50 nm to about 500 nm. In some embodiments, the thickness of the first layer of insulating material 305 and the second layer of insulating material 307 may range from about 100 nm to about 500 nm, from about 200 nm to about 500 nm, from about 300 nm to about 500 nm, from about 400 nm to about 500 nm, from about 50 nm to about 100 nm, from about 50 nm to about 200 nm, from about 50 nm to about 300 nm, from about 50 nm to about 400 nm, from about 100 nm to about 200 nm, from about 200 nm to about 300 nm, or from about 300 nm to about 400 nm. In other embodiments, the thickness of the first layer of insulating material 305 and the second layer of insulating material 307 may be about 50 nm, about 100 nm, about 200 nm, about 300 nm, about 400 nm, or about 500 nm. The first layer of insulating material 305 and the second layer of insulating material 307 may be deposited on the base layer 302 by using conventional techniques, such as but not limited to photolithography and chemical vapor deposition (CVD), for example. Such methods may be performed in a clean room.

Next, the uncovered portion of the base layer 302 is removed from the first support 300 until the first layer of insulating material 305 is exposed to form at least one opening 304 in the other side of the base layer 302, as illustrated in FIG. 3B. The uncovered portion of the base layer 302 may be removed from the first support 300 by an etching process, where the second layer of insulating material 307 is used as an etching mask.

The opening 304 may be formed to have various sizes and shapes. The size of the opening 304 may range from about 50 μm to about 1000 μm in width/length. In some embodiments, the size of the opening 304 may range from about 100 μm to about 1000 μm, from about 200 μm to about 1000 μm, from about 400 μm to about 1000 μm, from about 600 μm to about 1000 μm, from about 800 μm to about 1000 μm, from about 50 μm to about 100 μm, from about 50 μm to about 200 μm, from about 50 μm to about 400 μm, from about 50 μm to about 600 μm, from about 50 μm to about 800 μm, from about 100 μm to about 200 μm, from about 200 μm to about 400 μm, from about 400 μm to about 600 μm, or from about 600 μm to about 800 μm in width/length. In other embodiments, the size of the opening 304 may be about 50 μm, about 100 μm, about 200 μm, about 400 μm, about 600 μm, about 800 μm, or about 1000 μm in width/length.

Then, a layer of metal-containing material 306 is deposited on the first layer of insulating material 305, as illustrated in FIG. 3C. In some embodiments, the layer of metal-containing material 306, e.g., a metal layer, may be deposited by physical vapor deposition methods, such as but not limited to, sputtering, E-beam evaporation, thermal evaporation, laser molecular beam epitaxy, pulsed laser deposition, etc. The layer of metal-containing material 306 may be deposited on the entire surface of the first layer of insulating material 305. The thickness of the layer of metal-containing material 306, e.g., a metal layer, may range from about 1 nm to about 50 nm. In some embodiments, the thickness of the layer of metal-containing material 306 may range from about 5 nm to about 50 nm, from about 10 nm to about 50 nm, from about 20 nm to about 50 nm, from about 30 nm to about 50 nm, from about 40 nm to about 50 nm, from about 1 nm to about 5 nm, from about 1 nm to about 10 nm, from about 1 nm to about 20 nm, from about 1 nm to about 30 nm, from about 1 nm to about 40 nm, from about 5 nm to about 10 nm, from about 10 nm to about 20 nm, from about 20 nm to about 30 nm, or from about 30 nm to about 40 nm. In other embodiments, the thickness of the layer of metal-containing material 306 may be about 1 nm, about 5 nm, about 10 nm, about 20 nm, about 30 nm, about 40 nm, or about 50 nm.

In other embodiments, the layer of metal-containing material 306 may further include CNTs, such as but not limited to, SWNTs and MWNTs having a purity of about 80%, about 85%, about 90%, about 95%, and about 99%. To maximize the mechanical properties of the nanomembrane including CNTs, the CNTs need to be purified before the CNT layer is deposited. Alternatively, purified CNTs can be purchased directly. A suitable purification method may comprise refluxing CNTs in nitric acid (e.g., about 2.5 M) and re-suspending the CNTs in water with a surfactant (e.g., sodium lauryl sulfate, sodium cholate) at pH 10, and then filtering the CNTs using a cross-flow filtration system. The resulting purified CNT suspension may then be passed through a filter, such as a polytetrafluoroethylene filter. Further, sonication may be conducted for about 1 hour at about 50° C. in nitric acid in order to purify the CNTs. The CNTs may be neutralized using deionized water after wet oxidization and then passed through a vacuum filtration device. The purified CNTs may be dispersed in methanol. If an ultrasonication treatment is carried out for 10-20 hours at 45 Hz, impurities, such as metal catalysts, are removed and the CNTs are cut into a length of about 1-2 μm. As a result, a well dispersed and stable CNT colloidal solution can be obtained.

Next, the first layer of insulating material 305 exposed within the opening 304 is removed from the support 300 until the layer of metal-containing material 306, i.e., the metal-containing nanomembrane is suspended over the at least one opening 304 of the first support 300, as illustrated in FIG. 3D. In some embodiments, the first layer of insulating material 305 may be removed from the first support 300 by reactive ion etching in a vacuum chamber. In other embodiments, the first layer of insulating material 305 may be removed from the first support 300 by wet etching using 85% phosphoric acid (H₃PO₄) at a temperature of about 180° C. The second layer of insulating material 307 may also be removed during the above step.

In some embodiments, the metal-containing nanomembrane 306 may include any metal capable of interacting with molecular species, such as but not limited to, Ti, Cr, Ni, Cu, Zn, Ag, Pt, Au, and combinations thereof. For example, when Au is contained in the nanomembrane, molecular species having a thiol functional group may bind to the nanomembrane.

FIGS. 4A-C show an illustrative embodiment of a method for fabricating a lower part of a sensor having a metal/CNT-containing nanomembrane. As illustrated in FIG. 4A, initially a layer of CNTs 418 may be deposited on a metal layer 406 formed on a first support including a base layer 402, a first layer of insulating material 405 deposited on one side of the base layer 402, and a second layer of insulating material 407. Optionally, an additional metal layer may be deposited on the CNT layer 418 to obtain a thicker metal/CNT-containing nanomembrane later (shown in FIG. 4C). The thickness of the metal layer 406 may range from about 1 nm to about 50 nm. In some embodiments, the thickness of the metal layer 406 may range from about 5 nm to about 50 nm, from about 10 nm to about 50 nm, from about 20 nm to about 50 nm, from about 30 nm to about 50 nm, from about 40 nm to about 50 nm, from about 1 nm to about 5 nm, from about 1 nm to about 10 nm, from about 1 nm to about 20 nm, from about 1 nm to about 30 mm, from about 1 nm to about 40 nm, from about 5 nm to about 10 nm, from about 10 nm to about 20 nm, from about 20 nm to about 30 nm, or from about 30 nm to about 40 nm. In other embodiments, the thickness of the metal layer 406 may be about 1 nm, about 5 nm, about 10 nm, about 20 nm, about 30 nm, about 40 nm, or about 50 nm. The thickness of the CNT layer 418 may range from about 0.1 nm to about nm. In some embodiments, the thickness of the CNT layer 418 may range from about 0.5 nm to about 5 nm, from about 1 nm to about 5 nm, from about 2 nm to about 5 nm, from about 3 nm to about 5 nm, from about 4 nm to about 5 nm, from about 0.1 nm to about 0.5 nm, from about 0.1 nm to about 1 nm, from about 0.1 nm to about 2 nm, from about 0.1 nm to about 3 nm, from about 0.1 nm to about 4 nm, from about 0.5 nm to about 1 nm, from about 1 nm to about 2 nm, from about 2 nm to about 3 nm, or from about 3 nm to about 4 nm. In other embodiments, the thickness of CNT layer 418 may be about 0.1 nm, about 0.5 nm, about 1 nm, about 2 nm, about 3 nm, about 4 nm, or about 5 nm.

In some embodiments, the CNT layer 418 may be deposited by using various techniques including, but not limited to, dip-coating, spin coating, bar coating, spraying, self-assembly, Langmuir-Blodgett deposition, and vacuum filtration. For example, a droplet of CNT colloidal solution with a mass concentration of 0.05 mg/ml in N,N-dimethylformamide may be dropped on the substrate and rotated for about 20 seconds with a rotation speed of about 4,000 rpm. The excess CNTs can be washed out with pure deionized water and the coated substrate can be dried by spinning for 20 seconds, which results in the formation of a CNT layer.

In other embodiments, the CNTs may be deposited by using self-assembled monolayers (SAMs) having differing affinities to CNTs. For example, the metal layer 406 may be coated with CNT-affinity SAMs (e.g., 16-mercaptohexadecanoic acid or aminoethanethiol) and CNT-nonaffinity SAMs (e.g. octadecyltrichlorosilane) in a specific pattern, before depositing the CNTs. Since the CNTs would be deposited only to the portion of the metal layer 406 coated with CNT-affinity SAMs, the CNTs can be selectively deposited on desired portions of the metal layer 406, e.g., the center part of the metal layer 406, which is later expected to be suspended over the opening 404 (shown in FIG. 4C).

Next, the first support having the metal layer 406 and the CNT layer 418, as shown in FIG. 4A may be treated with heat under vacuum, where the CNT layer 418 shrinks (due to the CNT's negative coefficient of thermal expansion) and the metal layer 406 expands (due to the metal's positive coefficient of thermal expansion), resulting in a penetration of the CNT layer 418 into the surface of the metal layer 406, as illustrated in FIG. 4B. The heat treatment may be carried out in an electric furnace, oven, or the like, under vacuum conditions, at a temperature of from about 200° C. to about 600° C. In some embodiments, the temperature for the heat treatment may range from about 200° C. to about 400° C., or from about 400° C. to about 600° C. In other embodiments, the temperature for the heat treatment may be about 200° C., about 400° C., or about 600° C. The time for the heat treatment may range, but not limited to, from about 5 seconds to 300 seconds. In some embodiments, the time for the heat treatment may range from about 10 seconds to about 300 seconds, from about 30 seconds to about 300 seconds, from about 60 seconds to about 300 seconds, from about 100 seconds to about 300 seconds, from about 200 seconds to about 300 seconds, from about 5 seconds to about 10 seconds, from about 5 seconds to about 30 seconds, from about 5 seconds to about 60 seconds, from about 5 seconds to about 100 seconds, from about 5 seconds to about 200 seconds, from about 10 seconds to about 30 seconds, from about 30 seconds to about 60 seconds, from about 60 seconds to about 100 seconds, or from about 100 seconds to about 200 seconds. In other embodiments, the time for the heat treatment may be about 5 seconds, about 10 seconds, about 30 seconds, about 60 seconds, about 100 seconds, about 200 seconds, or about 300 seconds.

Then, as illustrated in FIG. 4C, the first layer of insulating material 405 exposed within the opening 404 may be removed until the metal/CNT-containing nanomembrane 406 is suspended over the opening 404. In some embodiments, the first layer of insulating material 405 may be removed from the first support by reactive ion etching. The second layer of insulating material 407 may also be simultaneously removed during the above step.

The metal/CNT-containing nanomembrane configuration is stronger and more durable since the CNTs bridge any possible breaks in the nanomembrane and reduce the residual stress of the nanomembrane. Moreover, the homogeneous distribution of CNTs within the in-plane direction of the layer enhances the load-transfer characteristics under tensile loading, and the layering structure increases the load capacity under conditions of strong interfacial strength between the CNTs and metal. Since CNTs have good flexibility, the deflection capability of the nanomembrane is not substantially affected by the presence of the CNTs in the nanomembrane. Thus, the measurement of the capacitance change is also not substantially affected by the presence of the CNTs in the nanomembrane.

Referring now to FIGS. 5A-C, an illustrative embodiment of a method for making an upper part of a sensor is shown. The upper part of the sensor may be fabricated by first assembling at least one electrode 508 on a second support 510, as illustrated in FIG. 5A. The electrode 508 may be attached to the second support by using physical vapor deposition techniques, such as but not limited to, sputtering, E-beam evaporation, thermal evaporation, laser molecular beam epitaxy, pulsed laser deposition, and the like. The electrode 508 may be in the form of one electrode or an array of electrodes, for example. Next, at least one set of spacers 512 may be attached on the second support 510 or the electrode 508, as illustrated in FIG. 5B. The spacers 512 maintain the predetermined distance between the electrode 508 of the upper part of the sensor and the metal-containing nanomembrane 306 of the lower part of the sensor, after the two parts of the sensor are assembled. The spacers 512 may be made of any insulating materials or photoresist materials. In some embodiments, the spacers 512 is made of AZ1512, which can be purchased from AZ electronic materials (Shanghai, China). The thickness of the spacers 512 may range, but is not limited to, from about 1 nm to about 50 nm. In some embodiments, the thickness of the spacers 512 may range from about 5 nm to about 50 nm, from about 10 nm to about 50 nm, from about 20 nm to about 50 nm, from about 30 nm to about 50 nm, from about 40 nm to about 50 nm, from about 1 nm to about 5 nm, from about 1 nm to about 10 nm, from about 1 nm to about 20 nm, from about 1 nm to about 30 nm, from about 1 nm to about 40 nm, from about 5 nm to about 10 nm, from about 10 nm to about 20 nm, from about 20 nm to about 30 nm, or from about 30 nm to about 40 nm. In other embodiments, the thickness of the spacers 512 may be about 1 nm, about 5 nm, about 10 nm, about 20 nm, about 30 nm, about 40 nm, or about 50 nm.

In certain embodiments, the fabricated upper part of the sensor, as illustrated in FIG. 5B, may be assembled with the fabricated lower part of the sensor, as illustrated in FIG. 3D, to form a complete sensor comprising a metal-containing nanomembrane illustrated in FIG. 1. In other embodiments, the fabricated upper part of the sensor, as illustrated in FIG. 5B, may also be assembled with the fabricated lower part of a sensor, as illustrated in FIG. 4C, to form a complete sensor comprising a metal/CNT-containing nanomembrane. The at least one electrode 508 of the upper part of the sensor is positioned on one side of the metal-containing nanomembrane 306 of the lower part of the sensor, to allow the at least one electrode 508 to sense one or more interactions of the at least one molecular species with the metal-containing nanomembrane 306. The upper and lower parts of the sensor may be assembled by attaching the spacers of the fabricated upper part of the sensor, as illustrated in FIG. 5B, to the metal-containing nanomembrane of the fabricated lower part of the sensor, as illustrated in FIG. 3D or FIG. 4C, using an adhesive, such as but not limited to, an epoxy- or ceramic-based adhesive. The electrode may sense the interactions of the at least one molecular species with the metal-containing nanomembrane, as long as the distance between the nanomembrane and the electrode is such that the change of capacitance between the nanomembrane and the electrode resulting from the deflection of the nanomembrane could be measured by a detection unit.

When fabricating freestanding nanomembranes which are first manufactured separately and subsequently transferred onto a solid substrate, a drying process needs to be carried out, resulting in shrinkage and a tensile residual stress of the nanomembrane. The residual stress increases the bending rigidity of the nanomembrane like a fastened spring, decreasing the sensitivity of the nanomembrane-based sensor. In contrast, the method for making a sensor in accordance with the present disclosure, where a nanomembrane is directly formed on a support having an opening minimizes the externally caused tensile residual stress of the nanomembrane, as compared with the previous approaches.

In addition, the sensors as described herein may utilize miniaturized electrical detection units, such as capacitance meters, e.g., AD7746 Evaluation board (Analog Devices, Inc.), based on a low-noise differential capacitance measurement technique for detecting the nanoscale deflections of the nanomembrane caused by the adsorption of biomolecules, instead of the bulky optical detection units (e.g., laser reflection interferometers) required for cantilever type sensors. The capacitance measurement technique is more compact compared to the optical detection units, yet provides comparable detection sensitivity, e.g., about a 10 nM range in biomolecular concentration. Moreover, the sensors including the metal-containing nanomembranes do not have the bimetallic effect problem that exists in metal-coated silicon cantilever-based sensors. Furthermore, in contrast to the cantilever-based biosensors where the molecular species may bind to an undesired side of the cantilever and produce background signals, in the sensors as described herein, the molecular species are only capable of binding to one side of the metal-containing nanomembrane. For example, FIG. 2 shows that the metal-containing nanomembrane 206 of the illustrated sensor blocks the flow of the molecular species 216 from passing to the other side where the change of capacitance between the metal-containing nanomembrane 206 and the electrode 208 is measured. Thus, the detection part of the sensors described herein is physically isolated from the sensing nanomembrane surface, eliminating the possibility of the molecules attaching to undesired surfaces.

### EXAMPLES

The following example is provided for illustration of some embodiments of the present disclosure but is by no means intended to limit its scope.

### Example 1

### Detection of Anthrax DNA

The above illustrated sensor is used to detect anthrax DNA.

In order to immobilize single-stranded DNA probes on the nanomembrane of the sensor, a solution containing a 27-mer 5′ thiol-modified single-stranded DNA (5′-ATCCTTATCAATATTTAACAATAATCC-3′) (1.0 μM), 1-ethyl-3-(3-dimethylaminoprppyl)-carbodiimide (EDC, 40 mM) and 1-methylimidazole (1-MeIm, 10 mM) is prepared. A sensor according to the present disclosure having a gold-containing nanomembrane with a thickness of 25 nm suspended over a 120 μm×120 μm square opening is provided. The solution containing the 5′ thiol-modified single-stranded DNA probe is injected into the opening of the sensor at a flow rate of 1 μL/min by using syringe pump, where the single-stranded DNA probe is immobilized on the nanomembrane surface.

The capacitance changes are measured using AD7746 Evaluation board (Analog Devices, Inc.). A negative capacitance change, e.g., about −0.05 pF, indicates a upward bending of the nanomembrane by the probe molecules immobilizing on the top surface.

Next, a sodium phosphate buffer solution with a concentration of 0.1 M is prepared. Samples containing single-stranded DNAs, i.e., anthrax DNA (5′-GGATTATTGTTAAATATTGATAAGGAT-3′) (SEQ ID NO: 1) and a sequence noncomplementary to the anthrax DNA (5′-TTCGGCGGTGGCCCGCGGTCGCCTTCG-3′) (SEQ ID NO: 2) are prepared. The above sensors having the probe molecules immobilized on the nanomembrane surface are provided. Using one sensor, a buffer solution containing the noncomplementary sequence to anthrax DNA is injected into the opening of the sensor at a flow rate of 1 μL/min using a syringe pump. In another sensor, a buffer solution containing the target anthrax DNA (0.1 μM) is injected into the opening of the sensor at a flow rate of 1 μL/min using a syringe pump, to allow the target anthrax DNA to hybridize with the probe molecules immobilized on the nanomembrane surface of the sensor.

The capacitance changes are measured using AD7746 Evaluation board (Analog Devices, Inc.). While the noncomplementary sequence causes no substantial capacitance change, a positive capacitance change, e.g., about 0.002 pF, in the sensor where the target DNA is injected indicates that the target DNA has hybridized to the probe molecules on the nanomembrane, causing a downward deflection of the nanomembrane.

The same procedures are repeated with different concentrations of the target DNA, where a smaller or larger change in capacitance indicates an lower or higher target DNA concentration.

### EQUIVALENTS

The present disclosure is not to be limited in terms of the particular embodiments described in this application. Many modifications and variations can be made without departing from its spirit and scope, as will be apparent to those skilled in the art. Functionally equivalent methods and apparatuses within the scope of the disclosure, in addition to those enumerated herein, will be apparent to those skilled in the art from the foregoing descriptions. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods, reagents, compounds, or compositions, which can, of course, vary. It is also to be understood that the terminology used herein is for the purpose of describing particular embodiments only, and is not intended to be limiting.

Those skilled in the art will appreciate that, for this and other processes and methods disclosed herein, the functions performed in the processes and methods may be implemented in differing order. Furthermore, the outlined steps and operations are only provided as examples, and some of the steps and operations may be optional, combined into fewer steps and operations, or expanded into additional steps and operations without detracting from the essence of the disclosed embodiments.

The herein described subject matter sometimes illustrates different components contained within, or connected with, different other components. It is to be understood that such depicted architectures are merely illustrative, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected”, or “operably coupled”, to each other to achieve the desired functionality, and any two components capable of being so associated can also be viewed as being “operably couplable”, to each other to achieve the desired functionality. Specific examples of operably couplable include but are not limited to physically mateable and/or physically interacting components and/or wirelessly interactable and/or wirelessly interacting components and/or logically interacting and/or logically interactable components.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

What is claimed is:

1. A sensor comprising:
a first support having at least one opening;
a metal-containing nanomembrane associated with the at least one opening and configured to interact with at least one molecular species; and
at least one electrode configured to sense one or more interactions of the at least one molecular species with the metal-containing nanomembrane.

2. The sensor according to claim 1 further comprising:
at least one detection unit coupled to the metal-containing nanomembrane or the at least one electrode and configured to detect the at least one molecular species at least partially based on a capacitive response.

3. The sensor according to claim 2, wherein the at least one detection unit is configured to identify the capacitive response as a response that indicates the presence and/or concentration of the at least one molecular species.

4. The sensor according to claim 2, wherein the at least one detection unit is configured to detect a deflection of the metal-containing nanomembrane caused by the one or more interactions of the at least one molecular species with the metal-containing nanomembrane.

5. The sensor according to claim 1, wherein at least a portion of the metal-containing nanomembrane is suspended over the at least one opening.

6. The sensor according to claim 5, wherein the portion of the metal-containing nanomembrane that is suspended over the at least one opening of the first support has a width from about 50 μm to about 1000 μm.

7. The sensor according to claim 1, wherein the at least one electrode is positioned at a predetermined distance from the metal-containing nanomembrane.

8. The sensor according to claim 1, wherein the metal-containing nanomembrane is configured to bind the at least one molecular species.

9. The sensor according to claim 1, wherein the at least one electrode further comprises:
a second support associated with the at least one electrode; and
at least one set of spacers between the at least one electrode and the metal-containing nanomembrane.

10. The sensor according to claim 1, wherein the metal-containing nanomembrane comprises one or more metals selected from the group consisting of Ti, Cr, Ni, Cu, Zn, Ag, Pt, and Au.

11. The sensor according to claim 1, wherein the metal-containing nanomembrane further comprises carbon nanotubes.

12. The sensor according to claim 1, wherein the metal-containing nanomembrane has a thickness of from about 1 nm to about 50 nm.

13. A method for making a sensor comprising:
associating a metal-containing nanomembrane with an opening of a first support, wherein the metal-containing nanomembrane is configured to interact with at least one molecular species; and
positioning at least one electrode on one side of the metal-containing nanomembrane under conditions effective to allow the at least one electrode to sense one or more interactions of the at least one molecular species with the metal-containing nanomembrane.

14. The method according to claim 13 further comprising:
coupling at least one detection unit to the metal-containing nanomembrane or the at least one electrode, wherein the detection unit is configured to detect the at least one molecular species at least partially based on a capacitive response.

15. The method according to claim 14, wherein said detection unit is configured to detect a deflection of the metal-containing nanomembrane caused by the one or more interactions of the at least one molecular species with the metal-containing nanomembrane.

16. The method according to claim 13, wherein at least a portion of the metal-containing nanomembrane is suspended over the at least one opening.

17. The method according to claim 16, wherein the portion of the metal-containing nanomembrane that is suspended over the at least one opening of the first support has a width from about 50 μm to about 1000 μm.

18. The method according to claim 13, wherein the metal-containing nanomembrane is configured to bind the at least one molecular species.

19. The method according to claim 13, wherein said first support comprises:
a base layer;
a first layer of insulating material deposited on one side of the base layer; and a second layer of insulating material deposited on the other side of the base layer.

20. The method according to claim 19, wherein said associating a metal-containing nanomembrane with an opening of a first support comprises:
depositing the first layer of insulating material on one side of the base layer;
depositing the second layer of insulating material on the other side of the base layer, leaving a portion of the base layer uncovered;
removing the uncovered portion of the base layer from said support until the first layer of insulating material is exposed to form at least one opening in the other side of the base layer;
depositing a metal layer on the first layer of insulating material; and
removing the first layer of insulating material exposed within the at least one opening from said support until a metal-containing nanomembrane is suspended over the at least one opening of the first support.

21. The method according to claim 13, wherein the metal-containing nanomembrane comprises one or more metals selected from the group consisting of Ti, Cr, Ni, Cu, Zn, Ag, Pt, and Au.

22. The method according to claim 13, wherein the metal-containing nanomembrane further comprises carbon nanotubes.

23. The method according to claim 13, wherein the metal-containing nanomembrane has a thickness of from about 1 nm to about 50 nm.

24. The method according to claim 13, wherein said positioning at least one electrode comprises positioning the at least one electrode at a predetermined distance from the metal-containing nanomembrane.

25. The method according to claim 24, wherein said positioning at least one electrode comprises:
assembling at least one electrode on a second support; and
attaching at least one set of spacers between the at least one electrode and one side of the metal-containing nanomembrane.

26. A method for detecting at least one molecular species comprising a use of the sensor according to claim 1.

27. A device for detecting at least one molecular species comprising the sensor according to claim 1.
